(19) United States
(12) Patent Application Publication
(10) Pub. No.: US 2014/0261605 A1
(43) Pub. Date: Sep. 18, 2014

(54) THERMOELECTRIC CONVERSION MODULE

(71) Applicants: NATIONAL INSTITUTE OF ADVANCED INDUSTRIAL SCIENCE AND TECHNOLOGY, Tokyo (JP); KITAGAWA INDUSTRIES CO., LTD., Aichi (JP)

(72) Inventors: HIROKI KITANO, KASUGAI-SHI (JP); HIDEO YUMI, KASUGAI-SHI (JP); YASUHIRO KAWAGUCHI, KASUGAI-SHI (JP); KENTA TAKAGI, NAGOYA-SHI (JP); KIMIHIRO OZAKI, NAGOYA-SHI (JP)

(73) Assignees: NATIONAL INSTITUTE OF ADVANCED INDUSTRIAL SCIENCE AND TECHNOLOGY, TOKYO (JP); KITAGAWA INDUSTRIES CO., LTD., Aichi (JP)

(21) Appl. No.: 14/207,169

(22) Filed: Mar. 12, 2014

(30) Foreign Application Priority Data
Mar. 13, 2013 (JP) 2013-050644

(51) Int. Cl. H01L 35/04

(52) U.S. Cl. CPC H01L 35/04
USPC 136/200

(57) ABSTRACT

A thermoelectric conversion module according to one aspect of embodiments of the present invention as disclosed herein includes a plurality of layered planar bodies. Each of the plurality of layered planar bodies includes a base material having a planar shape, a plurality of p-type granular bodies made of a p-type thermoelectric material, and a plurality of n-type granular bodies made of an n-type thermoelectric material. The plurality of p-type granular bodies and the plurality of n-type granular bodies are held by the base material in such a manner as to be spaced apart from each other in a direction along a face of the base material crossing a layered direction of the plurality of layered planar bodies.

### CROSS-REFERENCE TO RELATED APPLICATIONS

This application claims the benefit of Japanese Patent Application No. 2013-050644 filed on Mar. 13, 2013 in the Japan Patent Office, the disclosures of which are incorporated herein by reference.

### BACKGROUND

The present invention relates to a thermoelectric conversion module utilized to perform thermoelectric power generation by the Seebeck effect and/or thermoelectric cooling (electronic cooling) by the Peltier effect.

A planar thermoelectric conversion module utilized to perform thermoelectric power generation and/or thermoelectric cooling is known. In an example of such a thermoelectric conversion module, a plurality of p-type elements made of a p-type thermoelectric material and a plurality of n-type elements made of an n-type thermoelectric material are arranged two-dimensionally. On both front and back faces of the thermoelectric conversion module, a plurality of electrodes are provided, and one of the p-type elements and one of the n-type elements are electrically connected to each other via each of the electrodes. Due to this, the plurality of p-type elements and the plurality of n-type elements are alternately connected in series.

When a temperature difference (temperature gradient) is applied between the front face and the back face of such a thermoelectric conversion module, the p-type element has a higher potential on a lower temperature side and has a lower potential on a higher temperature side, whereas the n-type element has a higher potential on a higher temperature side and has a lower potential on a lower temperature side. As a result, a current flows from the p-type element to the n-type element on the lower temperature side, and a current flows from the n-type element to the p-type element on the higher temperature side.

The p-type element and the n-type element as described above are produced by heating a raw material composition having the same composition as that of the p-type thermoelectric material and the n-type thermoelectric material to melt or sinter, and cutting out a block-shaped molded body by machining (cutting). The thus-produced p-type element and n-type element are arranged on a substrate and connected in series to each other. In such a production process of the thermoelectric conversion module, delicate precision machining is difficult because the thermoelectric materials are often hard and brittle, and, thus, it has been difficult to seek reduction in size and thickness of the thermoelectric conversion module. Moreover, there has also been a problem that the cut-out processing of the molded body reduces the yield.

Furthermore, there has been a problem that, when a thermoelectric material excellent in thermal conductivity is used, heat is easily conducted inside the element and, therefore, a sufficient temperature difference does not occur between both ends of the element even when a large temperature difference is applied to the front and back faces of the thermoelectric conversion module.

To solve these problems, in Japanese Patent No. 4524382, for example, a technique is suggested in which a large temperature difference can be caused between both ends of the element by devising a shape of the element, and in which reduction in size of the thermoelectric power generation module can also be achieved.

In this technique, at least one of the p-type element and the n-type element has a shape obtained by combining a plurality of spheres. In such an element, a narrow portion having the smallest cross sectional area is formed at a portion where adjacent spheres are joined to each other. Since heat flux is delayed at the narrow portion, heat is harder to be conducted between both ends of the element in such an element than in an element cut into a block shape. As a result, the temperature difference between both ends of the element becomes larger and, thus, thermoelectric conversion performance of the thermoelectric conversion module can be improved.

When performance (electromotive force) of each element is improved as described above, required performance can be secured even with a smaller element. Accordingly, it is possible to seek reduction in weight, thickness, and size of the thermoelectric conversion module.

### SUMMARY

However, room for improvement has been left in the above-described element (p-type element or n-type element) having a shape obtained by a combination of a plurality of spheres, in the following points.

First, when producing the element having a shape as described above from a plurality of spherical particles, it is necessary to join the respective particles to each other while maintaining a state in which the plurality of spherical particles are arranged in a row. Therefore, in a case where small spherical particles having a diameter of the order of several millimeters are used, there has been a problem that an enormous amount of time and effort is required to align the small spherical particles, and to join the particles to each other while maintaining such an aligned state.

When producing a thermoelectric conversion module using the p-type element and the n-type element having such a configuration, for example, longitudinal directions of a plurality of the p-type elements and a plurality of the n-type elements (i.e., directions in which the spheres constituting the respective element are aligned) are aligned uniformly to one direction; the respective elements are arranged such that the respective elements are spaced apart from each other; and the p-type elements and the n-type elements are alternately connected in series.

However, in the case of the element constituted by joining a plurality of small spherical particles having a diameter of the order of several millimeters, the size of the element itself is correspondingly small. Therefore, there has been a problem that an enormous amount of time and effort is required to align the longitudinal directions of such small elements to one direction, and to arrange and fix such elements at predetermined intervals.

In addition, in the case of the element having a configuration as described above, there exists a narrow portion as described above at a joint portion between the spherical particles. Due to this, there has been a problem that, in comparison with the element cut out into a block shape, it is difficult to secure mechanical strength at the narrow portion, and the structure of the element is likely to be fragile. In order to avoid breakage of the element at the narrow portion, the thermoelectric conversion module can be utilized only for usages in which excessive shock and/or vibration is not transmitted to the thermoelectric conversion module. Therefore, there has been a problem that usages of the thermoelectric conversion module are limited.

To be more specific, assuming that the thermoelectric conversion module is installed in an automobile or the like, for example, there is a risk that a certain amount of shock and/or vibration may be applied to the thermoelectric conversion module while the automobile is running. If there is a risk that such shock and/or vibration may lead to breakage of the element, it would be difficult to use the thermoelectric conversion module including such elements for the purpose of installation in automobiles.

Assuming that the thermoelectric conversion module is installed in a mobile device or the like, for example, there is a risk that, when the mobile device is dropped and/or bumped against something, a corresponding shock may be applied to the thermoelectric conversion module. If such shock may lead to breakage of the element, it would be difficult to use the thermoelectric conversion module including such elements for the purpose of installation in mobile devices.

It is preferable that one aspect of embodiments of the present invention as disclosed herein can provide a thermoelectric conversion module that includes elements constituted by a plurality of granular bodies, the module being able to be easily manufactured and having a good durability against shock and/or vibration.

The thermoelectric conversion module according to one aspect of the embodiments of the present invention as disclosed herein includes a plurality of layered planar bodies. Each of the plurality of layered planar bodies includes a base material having a planar shape; a plurality of p-type granular bodies made of a p-type thermoelectric material; and a plurality of n-type granular bodies made of an n-type thermoelectric material. The plurality of p-type granular bodies and the plurality of n-type granular bodies are held by the base material in such a manner as to be spaced apart from each other in a direction along a face of the base material crossing a layered direction of the plurality of layered planar bodies. The p-type granular bodies in a first planar body from among the plurality of layered planar bodies are electrically connected to the p-type granular bodies in at least one second planar body adjacent to the first planar body, and the p-type granular bodies in the plurality of layered planar bodies are thereby connected in series to each other to constitute a plurality of sets of p-type elements. The n-type granular bodies in the first planar body are electrically connected to the n-type granular bodies in the adjacent at least one second planar body, and the n-type granular bodies in the plurality of layered planar bodies are thereby connected in series to each other to constitute a plurality of sets of n-type elements. The planar bodies arranged at both ends in the layered direction of the plurality of layered planar bodies include the p-type granular bodies and the n-type granular bodies electrically connected to each other, to thereby form a series connection in which the p-type elements and the n-type elements alternate with each other.

The thus-configured thermoelectric conversion module can be manufactured far more easily in comparison with a thermoelectric conversion module having a configuration in which a plurality of elements are prepared in advance and then such elements are arranged in predetermined positions. Accordingly, improved productivity can be obtained.

More specifically, in the case of the thermoelectric conversion module according to the embodiment of the present invention as disclosed herein, in each of the planar bodies, the plurality of p-type granular bodies and the plurality of n-type granular bodies are held by the base material in such a manner as to be spaced apart from each other in the direction along an upper face and/or a lower face of the base material. Therefore, when preparing a planar body having such a configuration, a time-consuming operation such as arranging a plurality of small granular bodies in a row and joining the granular bodies to each other is unnecessary.

In the case of the thermoelectric conversion module according to the embodiment of the present invention as disclosed herein, by layering a plurality of the planar bodies, a series connection of the plurality of p-type granular bodies ranging over a plurality of layers of the planer bodies is formed, and a series connection of the plurality of n-type granular bodies ranging over a plurality of layers of the planer bodies is formed, to thereby constitute the plurality of sets of p-type elements and the plurality of sets of n-type elements. Accordingly, in manufacturing such a thermoelectric conversion module, the handling of the planar bodies is easy because the planar bodies are far larger than the granular bodies, and a time-consuming operation such as arranging the plurality of small granular bodies in a row and joining the granular bodies to each other is unnecessary.

In the case of the thermoelectric conversion module according to the embodiment of the present invention as disclosed herein, an operation of aligning the directions of the plurality of elements to one direction and arranging these elements at intervals thereamong is also completed at the point when the plurality of planar bodies are layered. Therefore, in contrast to the technique in which after the plurality of elements are prepared, directions of these elements are aligned to one direction and these elements are arranged at intervals thereamong, the time and effort required to arrange the plurality of elements can be reduced.

In short, a configuration like the thermoelectric conversion module according to the embodiment of the present invention as disclosed herein would eliminate the need for the operation of arranging the plurality of granular bodies themselves in a row to prepare the element and an operation of arranging such elements. Accordingly, productivity of the thermoelectric conversion module is improved in comparison with a thermoelectric conversion module having a configuration that requires these operations.

In the case of the thermoelectric conversion module according to the embodiments of the present invention as disclosed herein, in a state where the plurality of the planar bodies are layered and the plurality of sets of p-type elements and the plurality of sets of n-type elements are constituted, the base material is interposed among the adjacent elements. Therefore, even when shock and/or vibration is transmitted to the elements, the elements are supported by the base material. Accordingly, in the thermoelectric conversion module according to the embodiments of the present invention as disclosed herein, improved durability against shock and/or vibration can be obtained in comparison with a thermoelectric conversion module having a configuration including no counterpart of such base material provided therein (e.g., a configuration in which only a plurality of elements are arranged and a space exists among the elements).

In the thermoelectric conversion module according to an embodiment of the present invention as disclosed herein, the p-type granular bodies in the first planar body may be directly connected to the p-type granular bodies in the adjacent at least one second planar body. Similarly, the n-type granular bodies in the first planar body may be directly connected to the n-type granular bodies in the adjacent at least one second planar body.

According to the thus-configured thermoelectric conversion module, there exist no interposed objects such as conductors between the p-type granular bodies in the planar bodies adjacent to each other and between the n-type granular bodies in the planar bodies adjacent to each other. Therefore, deterioration of electric properties of the thermoelectric conversion module due to the existence of such interposed objects can be suppressed.

Alternatively, in the thermoelectric conversion module according to an embodiment of the present invention as disclosed herein, the p-type granular bodies in the first planar body may be electrically connected to the p-type granular bodies in the adjacent at least one second planar body via conductors. Similarly, the n-type granular bodies in the first planar body may be electrically connected to the n-type granular bodies in the adjacent at least one second planar body via conductors.

In the thus-configured thermoelectric conversion module, the p-type granular bodies in the planar bodies adjacent to each other are electrically connected to each other via the conductors, and the n-type granular bodies in the planar bodies adjacent to each other are also electrically connected to each other via the conductors. Therefore, the need to arrange the p-type granular bodies and the n-type granular bodies at positions enabling direct contact of the p-type granular bodies to each other and the n-type granular bodies to each other is reduced, and the degree of freedom of arrangement positions of the p-type granular bodies and the n-type granular bodies is increased. For example, it is possible to arrange the p-type granular bodies and the n-type granular bodies at the most suitable positions considering thermal properties, mechanical properties, and the like, while providing the conductors that electrically connect the p-type granular bodies to each other and the conductors that electrically connect the n-type granular bodies to each other, to thereby constitute desired elements.

As examples of such conductors, thin plates or thin films made of a highly conductive material (e.g., metal), adhesion layers formed of an anisotropically conductive adhesive, and the like can be given. The metal thin plates may be a metal material processed into planar plates or may be a metal material processed into a shape functioning as a spring, for example. Conductive films may be formed by a physical thin film forming method such as spattering and ion plating, or may be formed by a chemical thin film forming method such as non-electrolytic plating, for example. Alternatively, the conductors may be obtained by a combination of a metal material and thin films, such as a combination of metal thin plates and plating films, and a combination of metal thin plates and the anisotropically conductive adhesive, for example.

In the thermoelectric conversion module according to an embodiment of the present invention as disclosed herein, each of the plurality of p-type granular bodies and the plurality of n-type granular bodies may have flat faces formed by processing part of each of the plurality of p-type granular bodies and the plurality of n-type granular bodies to be flat. The flat face of each of the p-type granular bodies in the first planar body may be contacted or joined to the flat face of each of the p-type granular bodies in the adjacent at least one second planar body directly or via a conductor. The flat face of each of the n-type granular bodies in the first planar body may be contacted or joined to the flat face of each of the n-type granular bodies in the adjacent at least one second planar body directly or via a conductor.

In the thus-configured thermoelectric conversion module, the flat faces formed on each of the p-type granular bodies and the n-type granular bodies are utilized as contact faces or joint faces. Therefore, in comparison with a case where the p-type granular bodies and the n-type granular bodies not having such flat faces formed thereon are used, larger areas of interfaces that become the contact faces or the joint faces are easily secured, and more reliable electrical connection at the contact faces or the joint faces can thereby be established.

In the thermoelectric conversion module according to an embodiment of the present invention as disclosed herein, the flat faces may be substantially parallel to faces of the base material.

In the thus-configured thermoelectric conversion module, the flat faces can be formed substantially parallel to the faces of the base material after having the p-type granular bodies and the n-type granular bodies held by the base material. Therefore, in comparison with a thermoelectric conversion module obtained by forming the flat faces on each of the p-type granular bodies and the n-type granular bodies and then having each of the p-type granular bodies and the n-type granular bodies held by the base material, parallelism between the flat faces and the faces of the base material can be easily increased, and more reliable electrical connection by contact or joining can be established.

Another aspect of an embodiment of the present invention as disclosed herein is a method of manufacturing a thermoelectric conversion module. The method includes preparing p-type granular bodies and n-type granular bodies; aligning the prepared p-type granular bodies and n-type granular bodies on a plurality of base materials having a planar shape; and layering the plurality of base materials.

According to such a manufacturing method, it is possible to easily manufacture a thermoelectric conversion module that includes elements constituted by a plurality of granular bodies and has good durability against shock and/or vibration.

The aligning the prepared p-type granular bodies and n-type granular bodies on the plurality of base materials having a planar shape may include using an alignment tray having concave portions formed in predetermined positions thereon.

### BRIEF DESCRIPTION OF THE DRAWINGS

Embodiments of the present invention will be described below by way of example with reference to accompanying drawings, in which:

FIGS. 1A-1D are diagrams showing a thermoelectric conversion module according to an exemplary embodiment; FIG. 1A is a perspective view thereof, FIG. 1B is a plan view thereof, FIG. 1C is a front view thereof, and FIG. 1D is a bottom view thereof;

FIGS. 2A and 2B are diagrams showing the thermoelectric conversion module; FIG. 2A is a cross-sectional view taken along line IIA-IIA of FIG. 1B, and FIG. 2B is a cross-sectional view taken along line IIB-IIB of FIG. 1B;

FIGS. 3A and 3B are explanatory diagrams showing usage examples of the thermoelectric conversion module;

FIGS. 4A-4L are explanatory diagrams showing manufacturing procedures of the thermoelectric conversion module;

FIGS. 5A-5C are explanatory diagrams regarding a case where granular bodies are provided with flat faces;

FIGS. 6A and 6B are explanatory diagrams regarding a case where granular bodies are contacted or joined directly to each other; and

FIGS. 7A and 7B are explanatory diagrams regarding other cases; FIG. 7A is an explanatory diagram regarding a case where conductors having spring property are interposed between the granular bodies, and FIG. 7B is an explanatory diagram regarding a case where an anisotropically conductive adhesive is interposed between the granular bodies.

### DETAILED DESCRIPTION OF THE PREFERRED EMBODIMENTS

Exemplary embodiments of the present invention as disclosed herein are described with some specific cases.

[1] First Case

[Structure of Thermoelectric Conversion Module]

As shown in FIGS. 1A to 1D, a thermoelectric conversion module 1 includes a main body 2 having a plate shape and a plurality (eight in the present case) of terminals 3A to 3H extending from one longitudinal end of the main body 2.

The main body 2 includes two faces 2A and 2B each positioned on the opposite side of the other. Here, the face 2A is referred to as an upper face 2A and the face 2B is referred to as a lower face 2B just for convenience. However, depending on usage of the thermoelectric conversion module 1, the face 2A does not necessarily have to be an upper face and the face 2B does not necessarily have to be a lower face.

On the upper face 2A, a plurality (23 multiplied by eight lines in the present case) of conductors 5A and a plurality (four in the present case) of conductors 5B are provided. On the lower face 2B, a plurality (23 multiplied by eight lines in the present case) of conductors 6A, a plurality (two in the present case) of conductors 6B, and a plurality (three in the present case) of conductors 6C are provided. From among the above-described plurality of terminals 3A to 3H, the terminals 3A and 3H positioned at both ends are constituted by part of the conductors 6B, and the terminals 3B to 3G at positions other than the both ends are constituted by part of the conductors 6C.

The main body 2 is designed to have a configuration in which a plurality (five in the present case) of planar bodies 7 are layered. The planar bodies 7 positioned adjacent to each other may be bonded to each other with an adhesive, for example, or may not be bonded to each other as long as a layered state of the plurality of planar bodies 7 can be maintained. As a manner of maintaining the layered state without such bonding, it would be possible, for example, to enclose the layered plurality of planar bodies 7 in a package body (not shown) or to hold the layered plurality of planar bodies 7 with a holder that binds the layered plurality of planar bodies 7 so as not to allow them to be misaligned with each other.

As shown in FIGS. 2A and 2B, the planar bodies 7 each include a base material 10 having a plate-like shape, a plurality of p-type granular bodies 11 made of a p-type thermoelectric material, and a plurality of n-type granular bodies 12 made of an n-type thermoelectric material.

In the present case, the base material 10 is made of a highly heat-resistant resin material (polyether ether ketone (PEEK) in the present case). The p-type granular bodies 11 are made of Fe₂V_{0.9}Ti_{0.1}Al, which is one of the p-type thermoelectric materials, and the n-type granular bodies 12 are made of Fe₂VAl_{0.9}Si_{0.1}, which is one of the n-type thermoelectric materials. The p-type granular bodies 11 and the n-type granular bodies 12 are both designed to be spherical particles having a diameter of 0.5 mm, for example.

In each of the planar bodies 7, the plurality of p-type granular bodies 11 and the plurality of n-type granular bodies 12 are held by the base material 10 in such a manner as to be spaced apart from each other in a direction along an upper face and/or a lower face of the base material 10. Between the planar bodies 7 adjacent to each other, conductors 15 are disposed so that the p-type granular bodies 11 are electrically connected to each other and the n-type granular bodies 12 are electrically connected to each other. Due to this, a plurality of sets of p-type elements 21 and a plurality of sets of n-type elements 22 are constituted in the thermoelectric conversion module 1 as a whole.

In the present case, the above-described plurality of conductors 5A, 5B, 6A, 6B, 6C, 15 may all be constituted by Ni-plated Cu thin plates. Since the respective thermoelectric materials forming the above-described p-type granular bodies 11 and n-type granular bodies 12 both have good compatibility with Ni, a structure in which Ni coating is formed on a surface of the base material made of highly conductive material such as Cu would improve connection strength between each of the conductors and each of the granular bodies.

A set of the p-type elements 21 is constituted such that the five p-type granular bodies 11 stacked in the layered five planar bodies 7 are connected in series to each other via the four conductors 15 interposed therebetween. A set of the n-type elements 22 is constituted such that the five n-type granular bodies 12 stacked in the layered five planar bodies 7 are connected in series to each other via the four conductors 15 interposed therebetween.

The planar bodies 7 at both ends in a layering direction constitute the above-described upper face 2A and the lower face 2B of the main body 2. On the upper face 2A and the lower face 2B, the p-type granular bodies 11 and the n-type granular bodies 12 are electrically connected to each other via the above-described conductors 5A, 5B, 6A, 6B, and 6C, and this makes a configuration in which the above-described p-type elements 21 and n-type elements 22 are alternately connected in series.

The structure shown in FIG. 2A is formed in a position corresponding to the terminal 3A, and structures equivalent to this are also formed in positions corresponding to the terminals 3C, 3E, and 3G. The structure shown in FIG. 2B is formed in a position corresponding to the terminal 3B, and structures equivalent to this are also formed in positions corresponding to the terminals 3D, 3F, and 3H. This makes a configuration in which all of the p-type elements 21 and the n-type elements 22 included in the thermoelectric conversion module 1 are alternately connected in series between the terminal 3A and the terminal 3H.

As described above, all of the p-type elements 21 and the n-type elements 22 included in the thermoelectric conversion module 1 are alternately connected in series between the terminal 3A and the terminal 3H. Therefore, in order to achieve a maximum potential difference in the thermoelectric conversion module 1, it is recommendable to use the terminals 3A and 3H, and, in such a case, the terminals 3B to 3G do not have to be used.

Specifically, while the terminals 3A and 3H are used by being connected to a circuit side, the terminals 3B to 3G do not have to be connected to the circuit side. In such a case, although the terminals 3B to 3G are not used as terminals for drawing electric power, the conductors 6C constituting the terminals 3B to 3G serve to electrically connect the p-type elements 21 and the n-type elements 22 to each other.

The thermoelectric conversion module 1 can be divided into two at a position shown in FIG. 3A, or can be divided into four at positions shown in FIG. 3B. While FIG. 3B illustrates four divided bodies obtained by dividing the thermoelectric conversion module 1 at all of the three split positions into quarters, the thermoelectric conversion module 1 may be divided at only one split position into two divided bodies, i.e., a quarter and a three-quarters. Alternatively, the thermoelectric conversion module 1 may be divided at two split positions into three divided bodies, i.e., a quarter, a quarter, and a two-quarters. When such a division is performed, the terminals 3B to 3G can become terminals positioned at the utmost ends of a group of the elements connected in series.

For example, in the case where the thermoelectric conversion module 1 has been divided at the position shown in FIG. 3A into two, in one divided body, the terminals 3A and 3D become the terminals positioned at the utmost ends of the group of the elements connected in series, and the terminals 3A and 3D are connected to the circuit side. In the other divided body, the terminals 3E and 3H become the terminals positioned at the utmost ends of the group of the elements connected in series, and the terminals 3E and 3H are connected to the circuit side.

In short, since the conductor 6C has a substantially U-shape and is arranged in a position where both ends thereof project from the main body 2, the conductor 6C can cause the elements to be electrically connected to each other in a state where the U-shaped part is continuous, whereas the conductor 6C can be utilized as a terminal in a state where the U-shaped part has been split up.

[Method of Manufacturing Thermoelectric Conversion Module]

A method of manufacturing the thermoelectric conversion module 1 is described with reference to FIGS. 4A to 4L.

First, the above-described p-type granular bodies 11 and n-type granular bodies 12 are prepared using the above-described respective thermoelectric materials. A manner of granulating the respective thermoelectric materials is not limited in particular. However, for a practical example, the respective thermoelectric materials may be formed into spherical particles by an atomization method. Particles prepared by a centrifugal force atomization method or a plasma rotating electrode method can be high in sphericity and narrow in particle size distribution. Accordingly, by classifying the thus-obtained particles by a method such as using a twin roller or an electroformed mesh, the p-type granular bodies 11 and the n-type granular bodies 12 having a uniform particle size can be obtained. Alternatively, when a pulse addition orifice injection method or a Rayleigh atomization method is used, it is possible to directly prepare granular bodies having an extremely uniform particle size and, thus, the classification process can be omitted.

Next, as shown in FIG. 4A, the p-type granular bodies 11, a particle size of which has been made uniform by the above-described classification or by a method other than that, are placed on an alignment tray 31 having concave portions formed in predetermined positions thereon. The p-type granular bodies 11 are aligned to the positions corresponding to the concave portions on the alignment tray 31 using a known nesting machine or a feeder, and the p-type granular bodies 11 that are surplus are eliminated from the alignment tray 31.

Subsequently, as shown in FIG. 4B, the plurality of p-type granular bodies 11 aligned on the alignment tray 31 are suctioned by a suction nozzle 32, and, as shown in FIG. 4C, the plurality of p-type granular bodies 11 are lifted from the alignment tray 31 by the suction nozzle 32.

Then, as shown in FIG. 4D, the plurality of p-type granular bodies 11 are moved to a lower mold 34, and, as shown in FIG. 4E, the plurality of p-type granular bodies are placed in predetermined positions within the lower mold 34. After that, as shown in FIG. 4F, once the suction by the suction nozzle 32 is stopped and the suction nozzle 32 is separated away from the plurality of p-type granular bodies 11, placement of the p-type granular bodies 11 is completed.

In a similar manner, as shown in FIG. 4G, the plurality of n-type granular bodies 12 are moved to the lower mold 34, and, as shown in FIG. 4H, the respective n-type granular bodies 12 are placed between the p-type granular bodies 11 or adjacent to the p-type granular bodies 11. After that, as shown in FIG. 41, once the suction by the suction nozzle 32 is stopped and the suction nozzle 32 is separated away from the plurality of n-type granular bodies 12, placement of the n-type granular bodies 12 is completed.

Next, as shown in FIG. 4J, the plurality of p-type granular bodies 11 and the plurality of n-type granular bodies 12, which have been aligned on the lower mold 34, are put between the lower mold 34 and an upper mold 35. Then, as shown in FIG. 4K, a resin material to become the base material 10 is poured into the space formed between the lower mold 34 and the upper mold 35 with a technique such as injecting molding. Upon hardening of the resin material, the lower mold 34 and the upper mold 35 are removed from the base material 10 as shown in FIG. 4L, and the planar body 7 (particles-embedded sheet) is completed.

As the resin material to become the base material 10, a resin material with high heat resistance may be selected considering that the thermoelectric conversion module 1 is to be arranged totally under high-temperature environment in a usage in which thermoelectric power generation is performed using the thermoelectric conversion module 1.

As representative examples of such a resin material with high heat resistance, engineering plastics such as liquid crystal polymer (LCP), polyphenylene sulfide (PPS), polyethylene naphthalate (PEN), polyimide (PI), polyamide (PA) can be given, for example, besides the above-described polyether ether ketone (PEEK).

On the thus-completed planar bodies 7, the conductors 15 are mounted at a position to become an interlayer when the planar bodies 7 are layered. At a position to become the upper face of the layered body when the plurality of planar bodies 7 are layered (i.e., the body obtained by layering the plurality of planar bodies 7), the conductors 5A and 5B are mounted, whereas at a position to become the lower face, the conductors 6A, 6B, 6C are mounted. The respective conductors 5A, 5B, 6A, 6B, 6C, 15 and the p-type granular bodies 11 or the n-type granular bodies 12 may be joined to each other. In such a case, it is possible to decrease electrical resistance between the respective conductors 5A, 5B, 6A, 6B, 6C, 15 and the p-type granular bodies 11 or the n-type granular bodies 12.

Although a specific joining method is not limited in particular, a method may be employed, for example, in which contact points are locally fused by resistance heating caused by a pulse current or the like passed through portions to be joined while applying pressure to the portions to thereby weld the contact points to each other. As a method of such localized fusion, laser heating may also be employed. Alternatively, it may be possible to interpose solder paste or the like between the portions to be joined and to perform solder joint by heating.

Alternatively, the respective conductors 5A, 5B, 6A, 6B, 6C, 15 and the p-type granular bodies 11 or the n-type granular bodies 12 may be just contacted to each other. In such a case, electrical connection between the respective conductors 5A, 5B, 6A, 6B, 6C, 15 and the p-type granular bodies 11 or the n-type granular bodies 12 can be at least maintained.

Some measures to maintain such contact may be taken. For example, in the case of the conductors 15, which are arranged at a position to become an interlayer, if the base materials 10 are joined to each other at a portion where the conductors 15 are not to be provided, joining of the conductors 15 themselves is not necessary. As a method of joining the base materials 10 to each other, a method of bonding the base materials 10 to each other with an adhesive, a method of thermally fusing the base materials 10 to each other, or the like may be employed.

As for the conductors 5A, 5B, 6A, 6B, 6C, 15, they can be arranged at desired positions by alternately layering the above-described particles-embedded sheets (planar bodies 7) and separately prepared resin sheets in which the conductors 5A, 5B, 6A, 6B, 6C, 15 are embedded (conductors-embedded sheets). Such conductors-embedded sheets can also be manufactured by insert molding or by embedding metal sheets later into preformed resin sheets.

Besides the above, a method may be employed in which: the p-type granular bodies 11 and the n-type granular bodies 12 are joined onto large-sized metal sheet in advance in a state arranged in predetermined positions; the metal sheet is embedded into resin; the metal sheet is patterned by etching or the like; and then such metal sheets are layered. Alternatively, a method may be employed in which, at the stage in which a single-layer particles-embedded sheet (planar body 7) is prepared, patterns are formed thereon that become the conductors 5A, 5B, 6A, 6B, 6C, 15 by physical vapor deposition and/or chemical film formation method, and the particles-embedded sheets on which the patterns are formed are layered.

[Effects]

According to the thermoelectric conversion module 1 as described above, by preparing the above-described planar bodies 7 and then layering them, the thermoelectric conversion module 1 having the plurality of sets of p-type elements 21 and the plurality of sets of n-type elements 22 can be constituted.

Accordingly, in comparison with a thermoelectric conversion module obtained by separately preparing elements corresponding to a plurality of sets of p-type elements and elements corresponding to a plurality of sets of n-type elements and then arranging the respective elements in predetermined positions, the thermoelectric conversion module 1 can be manufactured with greater ease. Therefore, the thermoelectric conversion module 1 can exert improved productivity.

The thermoelectric conversion module 1 has a configuration in which the base material 10 is interposed among the plurality of sets of p-type elements 21 and the plurality of sets of n-type elements 22. Therefore, in comparison with a thermoelectric conversion module having a configuration in which a constituent corresponding to the base material 10 is not provided (for example, a configuration in which only a plurality of elements are arranged and a space exists among the elements), the thermoelectric conversion module 1 can exert improved resistance to shock and/or vibration.

In the First Case, in the interlayer between the planar bodies 7 layered adjacent to each other, the p-type granular bodies 11 to be electrically connected to each other and the n-type granular bodies 12 to be electrically connected to each other are connected indirectly via the conductors 15. Therefore, it is not necessary to arrange the granular bodies at positions enabling direct contact thereof, and the degree of freedom of arrangement positions of the granular bodies is increased.

[2] Second Case

In the above-described First Case, an example is shown in which the p-type granular bodies 11 of a spherical shape and the n-type granular bodies 12 of a spherical shape are used to constitute the planar body 7. However, as shown in FIG. 5A, it may be possible, after the planar body 7 has been prepared, to trim part of the upper face and the lower face of the planar body 7 (e.g., down to a position indicated by alternate long and short dash lines in FIG. 5A) to thereby form flat faces 11A, 12A on the p-type granular bodies 11 of a spherical shape and the n-type granular bodies 12 of a spherical shape as shown in FIG. 5B.

In a case also where a configuration including the flat faces 11A, 12A as described above is adopted, it is possible to constitute a thermoelectric conversion module 51 having an approximately equivalent configuration to that of the thermoelectric conversion module 1 in the above-described First Case, as shown in FIG. 5C.

In the case of the thermoelectric conversion module 51, since the flat faces 11A, 12A are formed on the p-type granular bodies 11 and the n-type granular bodies 12, areas of interfaces to become contact surfaces or joint surfaces between the p-type granular bodies 11 or the n-type granular bodies 12 and the conductors 15, for example, are greater than those in the case of point contact as in the First Case.

Accordingly, electrical resistance at the interfaces is reduced, and more reliable electrical connection at the interfaces is secured. As a result, the thermoelectric conversion module 51 can have more improved electrical characteristics than the thermoelectric conversion module 1 in the First Case.

In the Second Case, the above-described flat faces 11A, 12A are formed by trimming the planar bodies 7 all over after having the p-type granular bodies 11 and the n-type granular bodies 12 held by the base material 10. When the flat faces 11A, 12A are formed in such a manner, the flat faces 11A, 12A become parallel to the upper face and/or the lower face of the base material 10 finally obtained.

Accordingly, in contrast to a case where respective granular bodies having flat faces formed thereon in advance are held by base material, the parallelism between the flat faces 11A, 12A and the upper face and/or the lower face of the base material 10 can be easily increased, and more reliable electrical connection at the contact surfaces or the joint surfaces can be secured.

In addition, when the planar body 7 is trimmed all over after having the p-type granular bodies 11 and the n-type granular bodies 12 held by the base material 10 as described above, it is possible to make uniform the sizes of the respective granular bodies in a thickness direction at the time when the flat faces 11A, 12A are formed, even if there is some variability in size between the p-type granular bodies 11 and the n-type granular bodies 12. Therefore, since the preparation of the granular bodies can be performed on the assumption that the sizes of the respective granular bodies in the thickness direction are to be made uniform in the above-described a manner, it is possible to save the trouble required for classification and the like of the granular bodies, and to improve productivity in comparison with the manufacturing process in which diameters of the granular bodies have to be made uniform with high accuracy.

[3] Third Case

In the above-described First Case and Second Case, in the interlayer between the planar bodies 7 layered adjacent to each other, the p-type granular bodies 11 to be electrically connected to each other and the n-type granular bodies 12 to be electrically connected to each other are connected indirectly via the conductors 15. However, as shown in FIG. 6A, the p-type granular bodies 11 may be connected directly to each other and the n-type granular bodies 12 may be directly connected to each other without the conductors 15.

In a case of a thus-configured thermoelectric conversion module 61, since there exist no interposed objects such as the conductors 15 between the granular bodies, it is possible to suppress deterioration of electrical characteristics caused by such interposed objects.

In the present Third Case as well, as shown in a thermoelectric conversion module 66 in FIG. 6B, the p-type granular bodies 11 and the n-type granular bodies 12 may be provided with the flat faces 11A, 12A as described in the Second Case, and the flat faces 11A, 12A may be contacted or joined to each other.

[4] Fourth Case

In a thermoelectric conversion module 71 shown in FIG. 7A, contact members 73 of metal with spring property are provided instead of the conductors 15 provided between the planar bodies 7 in the above-described respective cases. The contact members 73 are compressed when put between the planar bodies 7, and are thereby press-contacted to the p-type granular bodies 11 or the n-type granular bodies 12 positioned on both upper and lower sides of the contact members 73.

The contact members 73 as above are not joined to the p-type granular bodies 11 or the n-type granular bodies 12. Therefore, in order to appropriately maintain a press-contacted state to the p-type granular bodies 11 or the n-type granular bodies 12, the contact members 73 may be enclosed between the granular bodies by bonding or thermal fusion bonding the base materials 10 to each other between the planar bodies 7, for example.

[5] Fifth Case

In a thermoelectric conversion module 81 shown in FIG. 7B, the planar bodies 7 are bonded to each other with an anisotropically conductive adhesive, and anisotropically conductive adhesion layers 83 are formed between the planar bodies 7.

Although the anisotropically conductive adhesion layers 83 exhibit conductivity at respective positions in which the anisotropically conductive adhesion layers 83 are put between the p-type granular bodies 11 or the n-type granular bodies 12, the anisotropically conductive adhesion layers 83 do not exhibit conductivity around such respective positions. Therefore, a possibility is reduced that the p-type granular bodies 11 spaced apart from each other, the n-type granular bodies 12 spaced apart from each other, or the p-type granular bodies 11 and the n-type granular bodies 12 spaced apart from each other, may be electrically connected via the anisotropically conductive adhesion layers 83.

[6] Other Cases

The exemplary embodiments of the present invention have been described with several cases hereinabove. However, the present invention is not limited to the above-described specific cases, and can be implemented in various forms other than these.

For example, although Fe₂Val-based thermoelectric materials having a specific composition ratio are exemplified as a p-type thermoelectric material and an n-type thermoelectric material in the above-described cases, this composition ratio is an example and, thus, may be changed as appropriate within a range in which performance as p-type or n-type thermoelectric materials can be maintained. Although an example is shown, in the above-described cases, in which Si is added to Fe₂Val-based thermoelectric materials as a fourth element, an arbitrary fourth element may be added within a range in which performance as p-type or n-type thermoelectric materials can be maintained as well.

Although Fe₂Val-based thermoelectric materials are exemplified in the above-described cases, other thermoelectric materials may be used. As such thermoelectric materials, thermoelectric materials based on various alloys may be given, such as Bi—Te-based thermoelectric material, Mg—Si-based thermoelectric material, Mn—Si-based thermoelectric material, Fe—Si-based thermoelectric material, Si—Ge-based thermoelectric material, and Pb—Te-based thermoelectric material.

Although not mentioned in the above-described cases, the base material 10 may be hard and high in flexural rigidity or may be soft and low in flexural rigidity by changing a type and/or thickness of resin material. If the base material 10 is low in flexural rigidity and flexibly transformable, a thermoelectric conversion module having a band shape can be used by being wound around a heat source, or can be arranged along a curved heat surface.

What is claimed is:

1. A thermoelectric conversion module comprising a plurality of layered planar bodies,
wherein each of the plurality of layered planar bodies includes:
a base material having a planar shape;
a plurality of p-type granular bodies made of a p-type thermoelectric material; and
a plurality of n-type granular bodies made of an n-type thermoelectric material,
wherein the plurality of p-type granular bodies and the plurality of n-type granular bodies are held by the base material in such a manner as to be spaced apart from each other in a direction along a face of the base material crossing a layered direction of the plurality of layered planar bodies,
wherein the p-type granular bodies in a first planar body from among the plurality of layered planar bodies are electrically connected to the p-type granular bodies in at least one second planar body adjacent to the first planar body, and the p-type granular bodies in the plurality of layered planar bodies are thereby connected in series to each other to constitute a plurality of sets of p-type elements,
wherein the n-type granular bodies in the first planar body are electrically connected to the n-type granular bodies in the adjacent at least one second planar body, and the n-type granular bodies in the plurality of layered planar bodies are thereby connected in series to each other to constitute a plurality of sets of n-type elements, and
wherein the planar bodies arranged at both ends in the layered direction of the plurality of layered planar bodies include the p-type granular bodies and the n-type granular bodies electrically connected to each other, to thereby form a series connection in which the p-type elements and the n-type elements alternate with each other.

2. The thermoelectric conversion module according to claim 1,
wherein the p-type granular bodies in the first planar body are directly connected to the p-type granular bodies in the adjacent at least one second planar body, and
wherein the n-type granular bodies in the first planar body are directly connected to the n-type granular bodies in the adjacent at least one second planar body.

3. The thermoelectric conversion module according to claim 1,
wherein the p-type granular bodies in the first planar body are electrically connected to the p-type granular bodies in the adjacent at least one second planar body via conductors, and
wherein the n-type granular bodies in the first planar body are electrically connected to the n-type granular bodies in the adjacent at least one second planar body via conductors.

4. The thermoelectric conversion module according to claim 1,
wherein each of the plurality of p-type granular bodies and the plurality of n-type granular bodies has flat faces formed by processing part of each of the plurality of p-type granular bodies and the plurality of n-type granular bodies to be flat,
wherein the flat face of each of the p-type granular bodies in the first planar body is directly contacted to the flat face of each of the p-type granular bodies in the adjacent at least one second planar body, and
wherein the flat face of each of the n-type granular bodies in the first planar body is directly contacted to the flat face of each of the n-type granular bodies in the adjacent at least one second planar body.

5. The thermoelectric conversion module according to claim 1,
wherein each of the plurality of p-type granular bodies and the plurality of n-type granular bodies has flat faces formed by processing part of each of the plurality of p-type granular bodies and the plurality of n-type granular bodies to be flat,
wherein the flat face of each of the p-type granular bodies in the first planar body is directly joined to the flat face of each of the p-type granular bodies in the adjacent at least one second planar body, and
wherein the flat face of each of the n-type granular bodies in the first planar body is directly joined to the flat face of each of the n-type granular bodies in the adjacent at least one second planar body.

6. The thermoelectric conversion module according to claim 1,
wherein each of the plurality of p-type granular bodies and the plurality of n-type granular bodies has flat faces formed by processing part of each of the plurality of p-type granular bodies and the plurality of n-type granular bodies to be flat,
wherein the flat face of each of the p-type granular bodies in the first planar body is contacted to the flat face of each of the p-type granular bodies in the adjacent at least one second planar body via a conductor, and
wherein the flat face of each of the n-type granular bodies in the first planar body is contacted to the flat face of each of the n-type granular bodies in the adjacent at least one second planar body via a conductor.

7. The thermoelectric conversion module according to claim 1,
wherein each of the plurality of p-type granular bodies and the plurality of n-type granular bodies has flat faces formed by processing part of each of the plurality of p-type granular bodies and the plurality of n-type granular bodies to be flat,
wherein the flat face of each of the p-type granular bodies in the first planar body is joined to the flat face of each of the p-type granular bodies in the adjacent at least one second planar body via a conductor, and
wherein the flat face of each of the n-type granular bodies in the first planar body is joined to the flat face of each of the n-type granular bodies in the adjacent at least one second planar body via a conductor.

8. The thermoelectric conversion module according to claim 4,
wherein the flat faces are substantially parallel to the face of the base material.

9. The thermoelectric conversion module according to claim 5,
wherein the flat faces are substantially parallel to the face of the base material.

10. The thermoelectric conversion module according to claim 6,
wherein the flat faces are substantially parallel to the face of the base material.

11. The thermoelectric conversion module according to claim 7,
wherein the flat faces are substantially parallel to the face of the base material.
